(19) United States
(12) Patent Application Publication
(10) Pub. No.: US 2026/0083008 A1
(43) Pub. Date: Mar. 19, 2026

(54) SEMICONDUCTOR PACKAGE

(71) Applicant: SAMSUNG ELECTRONICS CO., LTD., Suwon-si (KR)

(72) Inventors: Taejun KIM, Suwon-si (KR); Hwanyoung CHOI, Suwon-si (KR)

(73) Assignee: SAMSUNG ELECTRONICS CO., LTD., Suwon-si (KR)

(21) Appl. No.: 19/199,928

(22) Filed: May 6, 2025

(30) Foreign Application Priority Data
Sep. 19, 2024 (KR) 10-2024-0126947

(51) Int. Cl. H01L 25/16; G02B 6/12; H01L 23/00; H01L 23/13; H01L 23/31

(52) U.S. Cl. CPC H10W 90/00; G02B 6/12; H10W 70/68; H10W 74/111; H10W 90/724; H10W 90/792

(57) ABSTRACT

The present disclosure relates to a semiconductor package, and the semiconductor package according to an embodiment includes a substrate having a recess at an edge; a waveguide structure in the recess, the waveguide structure comprising an internal interconnector configured to be connected to an external interconnector; an optical integrated circuit above the waveguide structure, the optical integrated circuit optically connected to the waveguide structure; an electronic integrated circuit on the optical integrated circuit; a semiconductor chip on the electronic integrated circuit; a first conductive post connecting the substrate and the electronic integrated circuit; and a second conductive post connecting the substrate and the semiconductor chip, wherein a first side surface of the waveguide structure is aligned with a side surface of the substrate.

### CROSS-REFERENCE TO RELATED APPLICATION

This application claims priority to and the benefit of Korean Patent Application No. 10-2024-0126947 filed in the Korean Intellectual Property Office on Sep. 19, 2024, the entire contents of which are incorporated herein by reference.

### BACKGROUND

### 1. Field

The present disclosure relates to a semiconductor package.

### 2. Description of Related Art

A silicon photonics technology is the only solution that may cope with exponentially increasing intra/inter data center traffic and telecom traffic with a low optical propagation loss, low power consumption, a high bandwidth, and compatibility with a mature commercial complementary metal-oxide-semiconductor (CMOS) process. A silicon-photonics-based photonic integrated circuit (PIC) technology integrates various optical devices on a single chip to drastically reduce manufacturing and packaging costs and achieve size reduction.

A silicon-photonics-based PIC can be monolithically integrated with an electronic integrated circuit (EIC) into a single chip. Accordingly, a 3D integration structure according to the related art in which an EIC (or application specific integrated circuit (ASIC)) chip is flip-chip bonded to a silicon-photonics-based PIC chip can have an advantage of propagating a high-speed electric signal over a very short distance with little loss by flip-chip bonding the EIC (or ASIC) chip and the PIC chip through a solder bump without a long bonding wire

### SUMMARY

The present disclosure attempts to improve reliability and an integration level of a semiconductor package.

A semiconductor package according to an embodiment includes: a substrate having a recess at an edge; a waveguide structure in the recess, the waveguide structure comprising an internal interconnector configured to be connected to an external interconnector; an optical integrated circuit above the waveguide structure, the optical integrated circuit optically connected to the waveguide structure in a horizontal direction; an electronic integrated circuit on the optical integrated circuit in the horizontal direction; a semiconductor chip on the electronic integrated circuit in the horizontal direction; a first conductive post connecting the substrate and the electronic integrated circuit; and a second conductive post connecting the substrate and the semiconductor chip, wherein a first side surface of the waveguide structure is aligned with a side surface of the substrate in a vertical direction.

A semiconductor package according to an embodiment includes: a substrate having a recess; a waveguide structure in the recess, the waveguide structure comprising a waveguide array; an optical integrated circuit above the waveguide structure, the optical integrated circuit optically connected to the waveguide structure; an electronic integrated circuit on the optical integrated circuit; a semiconductor chip on the electronic integrated circuit; a first conductive post connecting the substrate and the electronic integrated circuit; and a second conductive post connecting the substrate and the semiconductor chip, wherein a first side surface of the electronic integrated circuit is not aligned with a first side surface of the optical integrated circuit in a vertical direction, and a first side surface of the semiconductor chip is not aligned with a second side surface of the electronic integrated circuit in the vertical direction.

A semiconductor package according to an embodiment includes: a substrate having a recess; a waveguide structure in the recess, the waveguide structure comprising a waveguide array; an optical integrated circuit above the waveguide structure, the optical integrated circuit optically connected to the waveguide structure; an electronic integrated circuit on the optical integrated circuit, wherein a center of the electronic integrated circuit is misaligned with a center of the optical integrated circuit in a vertical direction; a semiconductor chip on the electronic integrated circuit, wherein a center of the semiconductor chip being is misaligned with the center of the electronic integrated circuit in the vertical direction; a redistribution structure above the substrate; first conductive post electrically connecting the redistribution structure and the electronic integrated circuit; and a second conductive post electrically connecting the redistribution structure and the semiconductor chip, wherein a distance between an upper surface of the waveguide structure and a lower surface of the substrate is equal to a distance between an upper surface of the redistribution structure and the lower surface of the substrate, and wherein a side surface of the waveguide structure is aligned with a side surface of the substrate in the vertical direction.

According to the embodiments, it is possible to improve reliability and an integration level of the semiconductor package.

### BRIEF DESCRIPTION OF DRAWINGS

FIG. 1 is an exemplary cross-sectional view illustrating a semiconductor package according to an embodiment;

FIG. 2 is an exemplary cross-sectional view illustrating a semiconductor package according to an embodiment;

FIG. 3 is a schematic block diagram illustrating components of the semiconductor package according to an embodiment;

FIG. 4 is a cross-sectional view illustrating an optical integrated circuit of the semiconductor package according to an embodiment;

FIG. 5 is an exemplary cross-sectional view illustrating a semiconductor package according to an embodiment;

FIG. 6 is an exemplary cross-sectional view illustrating a semiconductor package according to an embodiment;

FIG. 7 is an exemplary cross-sectional view illustrating a semiconductor package according to an embodiment;

FIG. 8 is an exemplary cross-sectional view illustrating a semiconductor package according to an embodiment;

FIG. 9 is an exemplary cross-sectional view illustrating a semiconductor package according to an embodiment;

FIG. 10 is an exemplary cross-sectional view illustrating a semiconductor package according to an embodiment;

FIG. 11 is an exemplary cross-sectional view illustrating a semiconductor package according to an embodiment;

FIG. 12 is an exemplary cross-sectional view illustrating a semiconductor package according to an embodiment;

FIG. 13 is an exemplary cross-sectional view illustrating a semiconductor package according to an embodiment;

FIG. 14 is an exemplary cross-sectional view illustrating a semiconductor package according to an embodiment;

FIG. 15 is an exemplary cross-sectional view illustrating a semiconductor package according to an embodiment;

FIG. 16 is an exemplary cross-sectional view illustrating a semiconductor package according to an embodiment;

FIG. 17 is an exemplary cross-sectional view illustrating a semiconductor package according to an embodiment;

FIG. 18 is an exemplary cross-sectional view illustrating a semiconductor package according to an embodiment;

FIG. 19 is an exemplary cross-sectional view illustrating a semiconductor package according to an embodiment;

FIG. 20 is an exemplary cross-sectional view illustrating a semiconductor package according to an embodiment; and

FIG. 21 is an exemplary cross-sectional view illustrating a semiconductor package according to an embodiment.

### DETAILED DESCRIPTION

Hereinafter, embodiments of the present disclosure will be described in detail with reference to the accompanying drawings so that those skilled in the art to which the present disclosure pertains may easily practice the present disclosure. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, since sizes and thicknesses of the respective components illustrated in the drawings are arbitrarily illustrated for convenience of explanation, the present disclosure is not necessarily limited to those illustrated in the drawings.

Throughout the present specification, when any one part or first part is referred to as being “connected to” another part or second part, it means that any one part and another part are “directly connected to” each other or are “indirectly connected to” each other with one or more parts interposed between any one part and another part. In addition, throughout the present specification, unless explicitly described to the contrary, the word “comprise” and variations such as “comprises” or “comprising”, will be understood to imply the inclusion of stated elements but not the exclusion of any other elements.

In addition, it will be understood that when an element such as a layer, a film, a region, or a plate is referred to as being “on” another element, it can be directly on the other element or intervening elements may also be present. In contrast, when an element is referred to as being “directly on” another element, there are no intervening elements present. In addition, when an element is referred to as being “on” a reference element, it may be positioned on or beneath the reference element, and is not necessarily positioned on the reference element in an opposite direction to gravity.

Further, throughout the specification, the term “plan view” refers to a view when a target is viewed from the top, and the term “cross-sectional view” refers to a view when a cross section of a target taken along a vertical direction is viewed from the side.

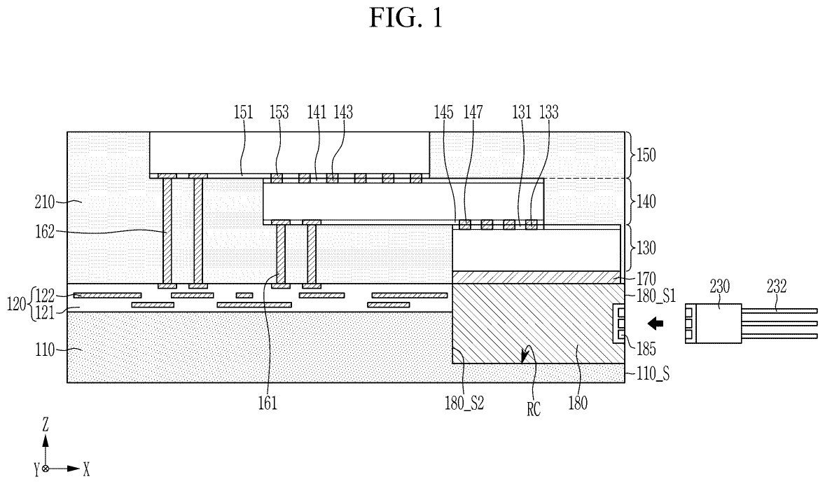

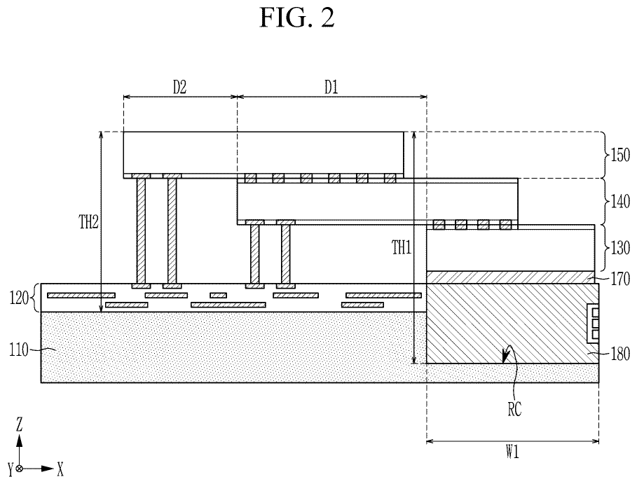

Hereinafter, a semiconductor package according to an embodiment will be described with reference to FIGS. 1 and 2.

FIGS. 1 and 2 are cross-sectional views illustrating the semiconductor package according to an embodiment.

The semiconductor package according to an embodiment may include a substrate 110, a waveguide structure 180 positioned on the substrate 110, an optical integrated circuit 130 positioned above the waveguide structure 180, an electronic integrated circuit 140 positioned on the optical integrated circuit 130, a semiconductor chip 150 positioned on the electronic integrated circuit 140, a first conductive post 161 connecting the substrate 110 and the electronic integrated circuit 140, and a second conductive post 162 connecting the substrate 110 and the semiconductor chip 150. The semiconductor package according to an embodiment may be a photonics semiconductor package.

The substrate 110 may be a substrate for a package, and may be, for example, a printed circuit board (PCB) or a ceramic substrate. In a case where the substrate 110 is a printed circuit board, the substrate 110 may be made of at least one material selected from a phenol resin, an epoxy resin, and a polyimide.

The substrate 110 may have an upper surface and a lower surface facing each other. The substrate 110 may include integrated circuits. The substrate 110 may include one or more routing lines.

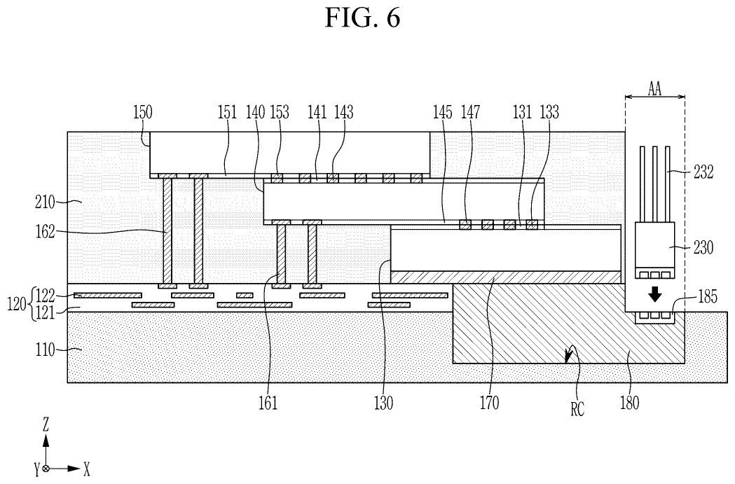

According to an embodiment, a recess RC may be positioned in the substrate 110. According to an embodiment, the recess RC may be positioned at an edge of the substrate 110. For example, the recess RC may be positioned at one end of the substrate 110, and a part of one side wall and a bottom surface of the recess RC may be defined by the substrate 110. Accordingly, the substrate 110 may have a step at the edge. However, the present disclosure is not limited thereto, and the recess RC may be positioned in the substrate 110, and opposite side walls of the recess RC may be defined by the substrate 110. A description thereof is provided below with reference to FIG. 6.

The semiconductor package according to an embodiment may further include a redistribution structure 120 positioned on the substrate 110.

The redistribution structure 120 may be positioned on the substrate 110. The redistribution structure 120 may be positioned directly on an upper surface of the substrate 110. The redistribution structure 120 may not be positioned in the recess RC or on the recess RC positioned in the substrate 110. A side surface of the redistribution structure 120 may be aligned with the same boundary as that of one sidewall of the recess RC. The redistribution structure 120 may be electrically connected to the routing line of the substrate 110.

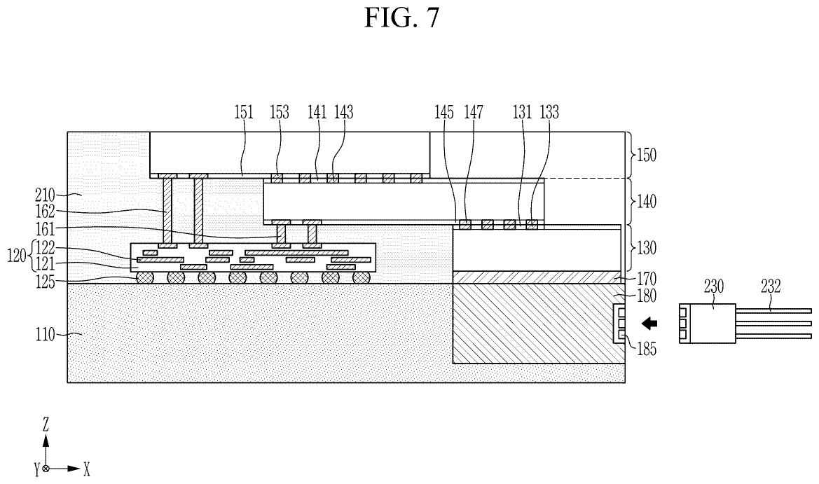

According to an embodiment, the redistribution structure 120 may include a plurality of insulating layers 121, a plurality of redistribution layers 122, and a plurality of redistribution vias. According to an embodiment, the plurality of insulating layers 121 and the plurality of redistribution layers 122 of the redistribution structure 120 may be in contact with the upper surface of the substrate 110. For example, the plurality of redistribution layers 122 of the redistribution structure 120 may be in direct contact with and electrically connected to the routing lines positioned in the substrate 110. However, the present disclosure is not limited thereto, and according to an embodiment, the redistribution structure 120 may have a chip shape and may be electrically connected to the substrate 110 through bumps connected to the plurality of redistribution layers 122. A description thereof is provided below with reference to FIG. 7.

The plurality of insulating layers 121 may protect and insulate the plurality of redistribution layers 122. The conductive posts 161 and 162 described below may be positioned on an upper surface of the plurality of insulating layers 121. The substrate 110 may be positioned on a lower surface of the plurality of insulating layers 121.

The plurality of insulating layers 121 may contain an insulating resin. The insulating resin may include a thermosetting resin such as an epoxy resin, a thermoplastic resin such as a polyimide, or a resin in which the thermosetting resin or the thermoplastic resin is impregnated with an inorganic filler or/and glass fiber (glass cloth or glass fabric). Examples include, but are not limited to a photosensitive resin such as prepreg, Ajinomoto Build up Film (ABF), FR-4, Bismaleimide Triazine (BT), or photo-imageable dielectric (PID). The plurality of insulating layers 121 may be stacked in a vertical direction. Here, the vertical direction may mean a thickness direction of the redistribution structure 120 (that is, a third direction (Z direction)). A boundary between the plurality of insulating layers 121 may be unclear depending on a process, but the present disclosure is not limited thereto.

The plurality of redistribution layers 122 may extend in a horizontal direction (for example, a first direction (X direction) and/or a second direction (Y direction)). The plurality of redistribution layers 122 may be electrically connected to the substrate 110. For example, the plurality of redistribution layers 122 may be electrically connected to the routing lines positioned in the substrate 110. The plurality of redistribution layers 122 may be electrically connected to the electronic integrated circuit 140 and/or the semiconductor chip 150 described below. The plurality of redistribution layers 122 may contain a conductive material. The plurality of redistribution layers 122 may contain a metal material including, for example, copper (Cu), aluminum (Al), silver (Ag), tin (Sn), gold (Au), nickel (Ni), lead (Pb), titanium (Ti), or an alloy thereof.

The waveguide structure 180 may be positioned on the substrate 110. The waveguide structure 180 may be positioned in the recess RC of the substrate 110. That is, the waveguide structure 180 may be embedded, partially in some embodiments and completely in other embodiments, in the substrate 110. At this time, an upper surface of the waveguide structure 180 may protrude in the vertical direction (Z direction) from the upper surface of the substrate 110. That is, the upper surface of the waveguide structure 180 may be positioned at a higher level than the upper surface of the substrate 110. The upper surface of the waveguide structure 180 may be positioned further from the lower surface of the substrate 110 than the upper surface of the substrate 110.

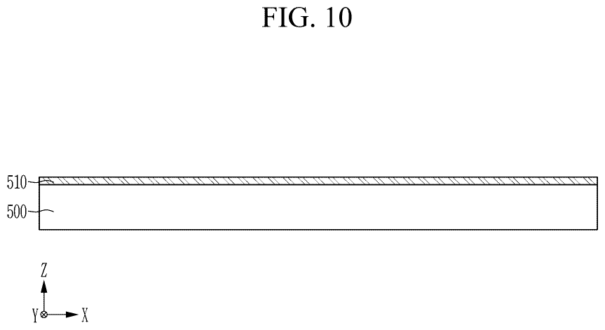

According to an embodiment, the upper surface of the waveguide structure 180 may be positioned at substantially the same level as an upper surface of the redistribution structure 120. The upper surface of the waveguide structure 180 may be positioned at substantially the same distance from the lower surface of the substrate 110 as the upper surface of the redistribution structure 120. Accordingly, the upper surface of the waveguide structure 180 may be positioned on the same plane as the upper surface of the redistribution structure 120. Therefore, the optical integrated circuit 130, the electronic integrated circuit 140, and the semiconductor chip 150 may be easily mounted on the redistribution structure 120 and the waveguide structure 180. A description thereof is provided below with reference to FIG. 10 and subsequent drawings. In embodiments, a distance between an upper surface of the redistribution structure 120 and a bottom surface of the substrate 110 may be the same as the distance between an upper surface of the waveguide layer 170 and the bottom surface of the substrate 110. Accordingly, the upper surface of the waveguide layer 170 may be positioned on the same plane as the upper surface of the redistribution structure 120. Therefore, the optical integrated circuit 130, the electronic integrated circuit 140, and the semiconductor chip 150 may be easily mounted on the redistribution structure 120 and the waveguide layer 170.

According to an embodiment, a side surface of the waveguide structure 180 may be aligned with the same boundary as that of a side surface 110_S of the substrate 110. a side surface of the waveguide structure 180 may be aligned with a side surface 110_S of the substrate 110 in the vertical direction (Z direction). For example, the waveguide structure 180 may have a first side surface 180_S1 and a second side surface 180_S2 facing the first side surface 180_S1, and the first side surface 180_S1 of the waveguide structure 180 may be aligned with the same boundary as that of the side surface 110_S of the substrate 110. The first side surface 180_S1 of the waveguide structure 180 may be positioned at one end of the substrate 110. A first width W1 of the recess RC in the first direction (X direction) may be substantially the same as a width of the waveguide structure 180 in the first direction (X direction), but is not limited thereto. The second side surface 180_S2 of the waveguide structure 180 may be in contact with one side wall of the recess RC. In addition, the second side surface 180_S2 of the waveguide structure 180 may be in contact with a side surface of the rewiring structure 120, but is not limited thereto. The second side surface 180_S2 of the waveguide structure 180 may be aligned with the same boundary as that of a side surface of the optical integrated circuit 130 described below. The second side surface 180_S2 of the waveguide structure 180 may be aligned with a side surface of the optical integrated circuit 130 in the vertical direction (Z direction). The second side surface 180_S2 of the waveguide structure 180 may be opposite to the first side surface 180_S1.

The waveguide structure 180 may include an internal interconnector 185 connected to an external optical cable 232. The internal interconnector 185 may be optically connected to the external optical cable 232. For example, the internal interconnector 185 may be optically connected to an external interconnector 230 connected from the outside of the semiconductor package. The internal interconnector 185 may be connected to the external interconnector 230 to receive an optical signal from the external optical cable 232. According to an embodiment, the internal interconnector 185 may be an optical coupler and/or an optical fiber connector connected to the external optical cable 232. The internal interconnector 185 may be a plug type and may be fixed in the waveguide structure 180, but is not limited thereto.

According to an embodiment, the internal interconnector 185 may be positioned on one side of the waveguide structure 180. For example, the internal interconnector 185 may be positioned on the first side surface 180_S1 of the waveguide structure 180. The internal interconnector 185 may be embedded in the waveguide structure 180 to form a part of the first side surface 180_S1. Here, the first side surface 180_S1 of the waveguide structure 180 may mean the side surface of the waveguide structure 180 that is aligned with the side surface 110_S of the substrate 110.

The waveguide structure 180 may be optically connected to the optical integrated circuit 130 described below. The waveguide structure 180 may optically connect the external optical cable 232 and the optical integrated circuit 130 through the internal interconnector 185, the external interconnector 230, and/or the waveguide layer 170. According to an embodiment, the waveguide structure 180 may not be electrically and optically connected to the substrate 110, but is not limited thereto.

According to an embodiment, the waveguide structure 180 may further include a waveguide array optically connected to the optical integrated circuit 130. The optical signal transmitted from the external optical cable 232 may be transmitted to the optical integrated circuit 130 through the internal interconnector 185 and the waveguide array. That is, the waveguide array may have a high internal reflectivity and may thus function to implement an optical path that confines and transmits light therein. As an example, the waveguide array may include an optical fiber array. The optical fiber array may contain glass or plastic fiber. The inside and the outside of the optical fiber array may have different densities and refractive indices, so that light incident on the optical fiber array may be totally reflected within the optical fiber to implement the optical path. In embodiments, the waveguide array may include a silicon waveguide array, a silicon nitride waveguide array, and the like. As another example, the waveguide array may include a core layer and a plurality of cladding layers (lower cladding layers). In embodiments, the core layer may contain a dielectric material having a relatively high refractive index, and the plurality of cladding layers may contain a dielectric material having a relatively low refractive index. The waveguide array may be formed of a single structure or a plurality of structures.

According to an embodiment, the waveguide structure 180 may further include an optical coupler that couples and transmits and receives light incident from the external optical cable 232, but is not limited thereto.

The optical integrated circuit 130 may be positioned above the waveguide structure 180. The optical integrated circuit 130 may be mounted above the waveguide structure 180. The optical integrated circuit 130 may be positioned above the recess RC of the substrate 110. The optical integrated circuit 130 may be optically connected to the waveguide structure 180. The optical integrated circuit 130 may be optically connected to the external optical cable 232 through the waveguide structure 180. The optical integrated circuit 130 may receive the optical signal from the external optical cable 232. In addition, the optical integrated circuit 130 may be electrically connected to the electronic integrated circuit 140 described below. In embodiments, the optical integrated circuit 130 may be positioned above the waveguide layer 170 which is on a same plane as a top surface of the redistribution layer 120.

According to an embodiment, the optical integrated circuit 130 may be a photonic integrated circuit (PIC). The optical integrated circuit 130 may receive the optical signal, convert the optical signal into an analog electric signal (for example, a current or a voltage), and transmit the analog electric signal to the electronic integrated circuit 140. In addition, the optical integrated circuit 130 may receive an electric signal, generate light, and modulate the light to generate an optical signal. The generated optical signal may be transmitted to the external optical cable 232 through the waveguide structure 180.

According to an embodiment, the side surface of the optical integrated circuit 130 may be aligned with the same boundary as that of the side surface of the waveguide structure 180. For example, a width of the optical integrated circuit 130 in the first direction (X direction) may be the same as the width of the waveguide structure 180 in the first direction (X direction). The side surfaces of the optical integrated circuit 130 may be aligned with the same boundaries as the first side surface 180_S1 and the second side surface 180_S2 of the waveguide structure 180, respectively. That is, the side surface of the optical integrated circuit 130 may be aligned with the same boundary as that of the side surface 110_S of the substrate 110, but is not limited thereto. The optical integrated circuit 130 may completely overlap the waveguide structure 180 in the vertical direction (Z direction). In addition, the optical integrated circuit 130 may not overlap the redistribution structure 120 in the vertical direction (Z direction). However, the present disclosure is not limited thereto, and only a part of the optical integrated circuit 130 may overlap the waveguide structure 180 in the vertical direction (Z direction). Alternatively, a part of the optical integrated circuit 130 may overlap the redistribution structure 120 in the vertical direction (Z direction).

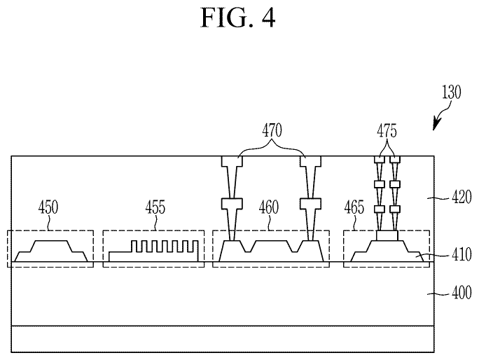

According to an embodiment, the optical integrated circuit 130 may include various optical components. For example, the optical integrated circuit 130 may include a waveguide member 450 (FIG. 4), a grating coupler 455 (FIG. 4), an optical modulator 460 (FIG. 4), and a photodetector 465 (FIG. 4). The optical components of the optical integrated circuit 130 will be described in more detail with reference to FIG. 4.

According to an embodiment, the optical integrated circuit 130 may have a chip-to-chip (C2C) structure bonded to the electronic integrated circuit 140 by a wafer bonding method (for example, hybrid bonding). That is, an upper surface of the optical integrated circuit 130 may be bonded to a lower surface of the electronic integrated circuit 140 by hybrid bonding. A description thereof is provided below in the description of the electronic integrated circuit 140.

The semiconductor package according to an embodiment may further include a waveguide layer 170 positioned between the waveguide structure 180 and the optical integrated circuit 130. The waveguide layer 170 may be aligned with the same boundary as that of the side surface of the waveguide structure 180 and may have the same widths in the X and Y directions.

The waveguide layer 170 may be positioned between the waveguide structure 180 and the optical integrated circuit 130. The waveguide layer 170 may optically connect between the waveguide structure 180 and the optical integrated circuit 130. Accordingly, the optical integrated circuit 130 may be optically connected to the external optical cable 232 through the waveguide layer 170 and the waveguide structure 180.

A side surface of the waveguide layer 170 may be aligned with the same boundary as that of the side surface of the waveguide structure 180. For example, one side surface of the waveguide layer 170 may be aligned with the same boundary as that of the second side surface 180_S2 of the waveguide structure 180. Meanwhile, the other side surface of the waveguide layer 170 that faces the one side surface of the waveguide layer 170 in the first direction (X direction) may not be aligned with the same boundary as that of the second side surface 180_S2 of the waveguide structure 180, but the present disclosure is not limited thereto. A width of the waveguide layer 170 in the first direction (X direction) may be smaller than or equal to the width of the waveguide structure 180 in the first direction (X direction), but is not limited thereto.

The waveguide layer 170 may include a waveguide. The waveguide may function to implement an optical path that confines and transmits light therein. For example, the waveguide layer 170 may include an optical fiber, a silicon waveguide, a silicon nitride waveguide, and a waveguide including a cladding layer and a core layer, but is not limited thereto.

The electronic integrated circuit (EIC) 140 may be positioned on the optical integrated circuit 130. The electronic integrated circuit 140 may be electrically connected to the optical integrated circuit 130.

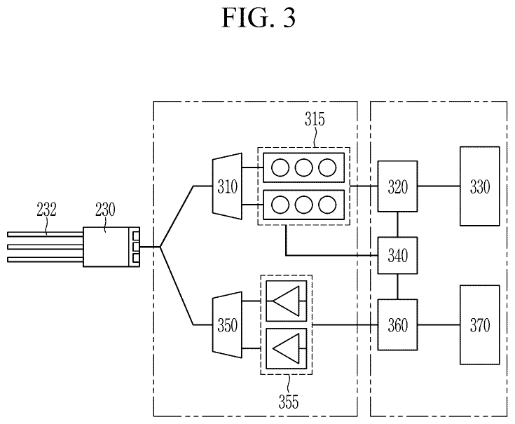

The electronic integrated circuit 140 may include various electronic components that control an operation of the optical integrated circuit 130. For example, the electronic integrated circuit 140 may include a transimpedance amplifier (TIA) 360 (FIG. 3), a clock and data recovery (CDR), and one or more drivers (DRV). According to an embodiment, the transimpedance amplifier may be a current-to-voltage converter that may be implemented by one or more operational amplifiers. The transimpedance amplifier may amplify a current output of a photodetector of the optical integrated circuit 130 or another type of sensor to a usable voltage. However, the present disclosure is not limited thereto, and the electronic integrated circuit 140 may additionally include more electronic components.

In addition, the electronic integrated circuit 140 may be electrically connected to the substrate 110 and the semiconductor chip 150. For example, the electronic integrated circuit 140 may be electrically connected to the substrate 110 through the redistribution structure 120 via the first conductive post 161 described below.

The electronic integrated circuit 140 may be misaligned or may not be aligned with the optical integrated circuit 130. For example, a center of the electronic integrated circuit 140 may be misaligned or may not be aligned with a center of the optical integrated circuit 130 in the first direction (X direction). That is, the electronic integrated circuit 140 may protrude from one side of the optical integrated circuit 130 toward an inner inside of the substrate 110 and away from side surface 110_S of a substrate 110. At this time, as illustrated in FIG. 2, a first distance D1 by which the electronic integrated circuit 140 protrudes from one side of the optical integrated circuit 130 may be smaller than a width of the electronic integrated circuit 140 in the first direction (X direction). According to an embodiment, the electronic integrated circuit 140 and the optical integrated circuit 130 may form a step. For example, a side surface of the electronic integrated circuit 140 and the upper surface of the optical integrated circuit 130 may form a step.

Accordingly, one side surface of the electronic integrated circuit 140 may be aligned with a different boundary from that of one side surface of the optical integrated circuit 130. In addition, the other side surface of the electronic integrated circuit 140 that faces the one side surface of the electronic integrated circuit 140 in the first direction (X direction) may be aligned with a different boundary from that of the other side surface of the optical integrated circuit 130 that faces the one side surface of the optical integrated circuit 130 in the first direction (X direction). In embodiments, no side surface of the electronic integrated circuit 140 in the first direction may be aligned with the side surfaces of the optical integrated circuit 130 in the first direction. A part of the electronic integrated circuit 140 may overlap the optical integrated circuit 130 in the vertical direction (Z direction), and the remaining part of the electronic integrated circuit 140 may not overlap the optical integrated circuit 130 in the vertical direction (Z direction). Accordingly, a space for disposing a wiring (for example, the first conductive post 161) for electrically connecting between the electronic integrated circuit 140 positioned on the optical integrated circuit 130 and the redistribution structure 120 may be easily formed.

In addition, the side surface of the electronic integrated circuit 140 may be aligned with a different boundary from that of the side surface 180_S1 or 180_S2 of the waveguide structure 180. That is, the side surface of the electronic integrated circuit 140 may protrude from the second side surface 180_S2 of the waveguide structure 180 toward the inner side of the substrate 110. A part of the electronic integrated circuit 140 may overlap the waveguide structure 180 in the vertical direction (Z direction), and the remaining part of the electronic integrated circuit 140 may not overlap the waveguide structure 180 in the vertical direction (Z direction).

According to an embodiment, the optical integrated circuit 130 may have the chip-to-chip (C2C) structure bonded to the electronic integrated circuit 140 by the wafer bonding method (for example, hybrid bonding). That is, the upper surface of the optical integrated circuit 130 may be bonded to the lower surface of the electronic integrated circuit 140 by hybrid bonding.

According to an embodiment, a part of the upper surface of the optical integrated circuit 130 that is adjacent to the electronic integrated circuit 140 may be a bonding surface with the electronic integrated circuit 140. In addition, a part of the lower surface of the electronic integrated circuit 140 that is adjacent to the optical integrated circuit 130 may be a bonding surface with the optical integrated circuit 130.

Specifically, the optical integrated circuit 130 may include a first bonding insulating layer 131 and a first contact pad 133 penetrating through the first bonding insulating layer 131 on an upper side, and the electronic integrated circuit 140 may include a second bonding insulating layer 145 and a second contact pad 147 penetrating through the second bonding insulating layer 145 on a lower side. The first contact pad 133 and the second contact pad 147 may be bonded to each other in a contact state to form a metal bond. In addition, the first bonding insulating layer 131 and the second bonding insulating layer 145 may be bonded to each other to form a bonding insulating layer. In this way, the first contact pad 133 and the second contact pad 147 may be bonded to each other to provide an electrical connection path between the optical integrated circuit 130 and the electronic integrated circuit 140.

It is understood that the optical integrated circuit 130 and the electronic integrated circuit 140 may be bonded to each other by hybrid bonding but the present disclosure is not limited thereto. For example, the optical integrated circuit 130 and the electronic integrated circuit 140 of the semiconductor package according to some embodiments may be bonded to each other by metal-to-metal direct bonding, solder bonding, or the like.

The semiconductor chip 150 may be positioned on the electronic integrated circuit 140. The semiconductor chip 150 may be mounted on the electronic integrated circuit 140. The semiconductor chip 150 may be electrically connected to the electronic integrated circuit 140. In addition, the semiconductor chip 150 may be electrically connected to the substrate 110. For example, the semiconductor chip 150 may be electrically connected to the substrate 110 through the redistribution structure 120 via the second conductive post 162 described below. According to an embodiment, the semiconductor chip 150 may be an ASIC chip, but is not limited thereto. In another example, the semiconductor chip 150 may include at least one of a central processing unit (CPU), a graphics processing unit (GPU), a memory, a controller, a codec, a sensor, or a communication chip.

The semiconductor chip 150 may not be aligned or may be misaligned with the electronic integrated circuit 140. For example, a center of the semiconductor chip 150 may be misaligned or may not be aligned with the center of the electronic integrated circuit 140 in the first direction (X direction). That is, the semiconductor chip 150 may protrude from one side of the electronic integrated circuit 140 toward the inner side of the substrate 110 and away from side surface 110_S of a substrate 110. At this time, as illustrated in FIG. 2, a second distance D2 by which the semiconductor chip 150 protrudes from one side of the electronic integrated circuit 140 may be smaller than a width of the semiconductor chip 150 in the first direction (X direction). That is, the semiconductor chip 150 may overlap the electronic integrated circuit 140 in the vertical direction. According to an embodiment, the semiconductor chip 150 and the electronic integrated circuit 140 may form a step. For example, a side surface of the semiconductor chip 150 and an upper surface of the electronic integrated circuit 140 may form a step.

Accordingly, one side surface of the semiconductor chip 150 may be aligned with a different boundary from that of one side surface of the electronic integrated circuit 140. In addition, the other side surface of the semiconductor chip 150 that faces the one side surface of the semiconductor chip 150 in the first direction (X direction) may be aligned with a different boundary from that of the other side surface of the electronic integrated circuit 140 that faces the one side surface of the electronic integrated circuit 140 in the first direction (X direction). Accordingly, in an embodiment, neither side surface of the semiconductor chip 150 may be aligned with either side surface of the electronic integrated circuit 140. Accordingly, a part of the semiconductor chip 150 may overlap the electronic integrated circuit 140 in the vertical direction (Z direction), and the remaining part of the semiconductor chip 150 may not overlap the electronic integrated circuit 140 in the vertical direction (Z direction). Accordingly, a space for disposing a wiring (for example, the second conductive post 162) for electrically connecting between the semiconductor chip 150 positioned on the electronic integrated circuit 140 and the redistribution structure 120 may be easily formed.

According to an embodiment, the semiconductor chip 150 and the electronic integrated circuit 140 may have the chip-to-chip (C2C) structure bonded by the wafer bonding method (for example, hybrid bonding). That is, a lower surface of the semiconductor chip 150 may be bonded to the upper surface of the electronic integrated circuit 140 by hybrid bonding.

According to an embodiment, a part of a lower surface of a semiconductor chip 150 that is adjacent to the electronic integrated circuit 140 may be a bonding surface with the electronic integrated circuit 140. In addition, a part of the upper surface of the electronic integrated circuit 140 that is adjacent to the semiconductor chip 150 may be a bonding surface with the semiconductor chip 150.

Specifically, the electronic integrated circuit 140 may include a third bonding insulating layer 141 and a third contact pad 143 penetrating through the third bonding insulating layer 141 on an upper side, and the semiconductor chip 150 may include a fourth bonding insulating layer 151 and a fourth contact pad 153 penetrating through the fourth bonding insulating layer 151 on a lower side. The third contact pad 143 and the fourth contact pad 153 may be bonded to each other in a contact state to form a metal bond. In addition, the third bonding insulating layer 141 and the fourth bonding insulating layer 151 may be bonded to each other to form a bonding insulating layer. In this way, the third contact pad 143 and the fourth contact pad 153 may be bonded to each other to provide an electrical connection path between the electronic integrated circuit 140 and the semiconductor chip 150.

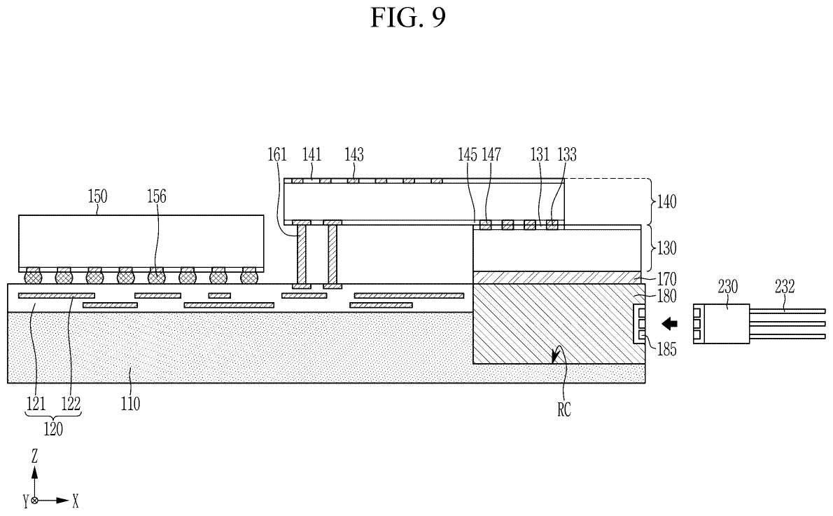

Embodiments herein describe the semiconductor chip 150 and the electronic integrated circuit 140 being bonded to each other by hybrid bonding. However, it is understood that the present disclosure is not limited thereto. For example, the semiconductor chip 150 and the electronic integrated circuit 140 of the semiconductor package according to some embodiments may be bonded to each other by metal-to-metal direct bonding, solder bonding, or the like. As another example, the semiconductor chip 150 may be mounted on the redistribution structure 120. A description thereof is provided below with reference to FIG. 9.

The semiconductor package according to an embodiment may further include a molding layer 210 surrounding the optical integrated circuit 130, the electronic integrated circuit 140, and the semiconductor chip 150.

The molding layer 210 may mold the waveguide structure 180, the optical integrated circuit 130, the electronic integrated circuit 140, and the semiconductor chip 150. The molding layer 210 may cover opposite side surfaces and the upper surface of the optical integrated circuit 130, opposite side surfaces and the upper surface of the electronic integrated circuit 140, and opposite side surfaces of the semiconductor chip 150. In addition, the molding layer 210 may cover the upper surface of the waveguide structure 180, but is not limited thereto. According to an embodiment, the molding layer 210 may not be positioned on an upper surface of the semiconductor chip 150. An upper surface of the molding layer 210 may be positioned on the same plane as the upper surface of the semiconductor chip 150. That is, the upper surface of the molding layer 210 may be positioned at substantially the same level as the upper surface of the semiconductor chip 150. The upper surface of the molding layer 210 may be positioned at substantially the same distance from the lower surface of the substrate 110 as the upper surface of the semiconductor chip 150. This may be due to process characteristics of forming the molding layer 210 after sequentially stacking the semiconductor chip 150, the electronic integrated circuit 140, and the optical integrated circuit 130 on a first carrier substrate 500 (FIG. 10), and then flipping and mounting the semiconductor chip 150, the electronic integrated circuit 140, and the optical integrated circuit 130 on the substrate 110.

The molding layer 210 of the semiconductor package according to an embodiment may surround the optical integrated circuit 130, the electronic integrated circuit 140, and the semiconductor chip 150. In this case, since the waveguide structure 180 is positioned at one end of the substrate 110, the first side surface 180_S1 of the waveguide structure 180 may be exposed without being covered by the molding layer 210. Accordingly, the internal interconnector 185 positioned on the first side surface 180_S1 of the waveguide structure 180 may be connected to the external interconnector 230 without performing a process of forming a separate recess in the molding layer 210 to expose at least a part of the waveguide structure 180. Accordingly, the optical integrated circuit 130, the electronic integrated circuit 140, and the semiconductor chip 150 may be effectively protected by the molding layer 210.

The conductive posts 161 and 162 may be positioned on the top surface of the redistribution structure 120. The conductive posts 161 and 162 may penetrate through the molding layer 210 and be positioned on the upper surface of the redistribution structure 120. Side surfaces of the conductive posts 161 and 162 may be surrounded by the molding layer 210. According to an embodiment, the conductive posts 161 and 162 may extend in the vertical direction (Z direction). The conductive posts 161 and 162 may be electrically connected to the redistribution structure 120.

For example, the first conductive post 161 may electrically connect the redistribution structure 120 and the electronic integrated circuit 140. The first conductive post 161 may be positioned between the redistribution structure 120 and a portion of the electronic integrated circuit 140 that does not overlap the optical integrated circuit 130 in the vertical direction (Z direction). The electronic integrated circuit 140 may be electrically connected to the substrate 110 through the redistribution structure 120 via the first conductive post 161.

The second conductive post 162 may electrically connect between the redistribution structure 120 and the semiconductor chip 150. The second conductive post 162 may be positioned between the redistribution structure 120 and a portion of the semiconductor chip 150 that does not overlap the electronic integrated circuit 140 in the vertical direction (Z direction). The semiconductor chip 150 may be electrically connected to the substrate 110 through the redistribution structure 120 via the second conductive post 162.

According to an embodiment, a length of the first conductive post 161 in the vertical direction (Z direction) may be smaller than a length of the second conductive post 162 in the vertical direction (Z direction). This is because the first conductive post 161 and the second conductive post 162 extend in the vertical direction (Z direction), the first conductive post 161 electrically connects between the electronic integrated circuit 140 and the redistribution structure 120, and the second conductive post 162 electrically connects between the semiconductor chip 150 positioned on the electronic integrated circuit 140 and the redistribution structure 120.

According to an embodiment, in the semiconductor package, the optical integrated circuit 130, the electronic integrated circuit 140, and the semiconductor chip 150 may be positioned in this order on the waveguide structure 180. As the waveguide structure 180, the optical integrated circuit 130, the electronic integrated circuit 140, and the semiconductor chip 150 are sequentially stacked in the vertical direction (Z direction), an area of the semiconductor package may be reduced and an integration level may be improved.

According to an embodiment, the semiconductor chip 150 may be mounted on the same substrate as the optical integrated circuit 130 and the electronic integrated circuit 140, and thus, an electric signal path may be relatively shortened. As a result, it is possible to achieve more efficient power consumption and higher bandwidth and improve reliability of the semiconductor package.

In addition, in the semiconductor package according to an embodiment, the waveguide structure 180 may be positioned in the recess RC of the substrate 110. Accordingly, even when the waveguide structure 180, the optical integrated circuit 130, the electronic integrated circuit 140, and the semiconductor chip 150 are stacked in the vertical direction (Z direction), a height of the semiconductor package may be reduced. That is, a second thickness TH2 from the upper surface of the substrate 110 to the upper surface of the semiconductor chip 150 may be smaller than a first thickness TH1 that is a total length of the waveguide structure 180, the optical integrated circuit 130, the electronic integrated circuit 140, and the semiconductor chip 150 stacked in the vertical direction (Z direction). Accordingly, the integration level of the semiconductor package may be improved.

Hereinafter, the semiconductor package according to an embodiment will be described with reference to FIG. 3.

FIG. 3 is a schematic block diagram illustrating components of the semiconductor package according to an embodiment.

The external interconnector 230 is an input/output port for the optical signal between the external optical cable 232 and the semiconductor package. Hereinafter, the respective components will be described by dividing a case of receiving the optical signal through the external optical cable 232 and a case of transmitting the optical signal.

Referring to FIG. 3, when the optical signal received through the external interconnector 230 reaches a plurality of photodetectors 355 through a demultiplexer (DEMUX) 350. The photodetector 355 may convert the optical signal into the analog electric signal. The transimpedance amplifier 360 may convert a current signal output from the photodetector 355 into a voltage signal. For example, the transimpedance amplifier may amplify a current output of the photodetector 355 of the optical integrated circuit 130 or another type of sensor to a usable voltage. The converted electric signal may be output to the outside through an output driver 370.

When the electric signal is received by an input buffer 330, a light source element may emit light based on the received electric signal, and a modulator driver 320 may drive a plurality of optical modulators 315 to modulate the light emitted from the light source element. The electronic components may be operated under the control of a controller 340. The modulated light may be transmitted to the external interconnector 230 through a multiplexer 310, and the optical signal may be transmitted through the external optical cable 232 connected to the external interconnector 230.

It should be understood that the semiconductor package according to an embodiment may include more optical components and electronic components in addition to the components described above, but only major components are introduced here for convenience of explanation.

In FIG. 3, the multiplexer 310, the plurality of optical modulators 315, the demultiplexer 350, and the plurality of photodetectors 355 are optical components included in the optical integrated circuit 130 (indicated in FIG. 3 in the dashed box), and the transimpedance amplifier 360, the output driver 370, the input buffer 330, the modulator driver 320, and the controller 340 may be electronic components included in the electronic integrated circuit 140 (indicated in FIG. 3 in the dotted-dashed box).

However, it is understood that the present disclosure is not limited thereto. In an embodiment, the optical integrated circuit 130 may be manufactured by a complementary metal-oxide-semiconductor (CMOS) process, and thus, the optical integrated circuit 130 may include some of the electronic components in addition to the optical components. The transimpedance amplifier 360, the output driver 370, the input buffer 330, the modulator driver 320, and the controller 340 may be classified according to the functions executed by the respective components. Such classification is not necessarily the same as physical classification. The electronic components of the electronic integrated circuit 140 may be implemented by a transistor array, and the optical components of the optical integrated circuit 130 may include a part of a transistor array.

Hereinafter, the optical integrated circuit of the semiconductor package according to an embodiment will be described with reference to FIG. 4.

FIG. 4 is a cross-sectional view illustrating the optical integrated circuit of the semiconductor package according to an embodiment.

Referring to FIG. 4, the optical integrated circuit 130 of the semiconductor package according to an embodiment may include a silicon layer 410 including a buried oxide layer 400. The optical integrated circuit 130 may also include the waveguide member 450, the grating coupler 455, the optical modulator 460, and the photodetector 465 positioned on the buried oxide layer 400.

The buried oxide layer (BOX layer) 400 may be positioned on a silicon-based member. The buried oxide layer 400 may be formed over an entire upper surface of the silicon-based member, or may be formed only on a part of the silicon-based member.

The silicon layer 410 may be positioned on the buried oxide layer 400. The silicon layer 410 may form the optical components. For example, the silicon layer 410 (highlighted using the dotted box in FIG. 4) may form the optical waveguide 450, the grating coupler 455, the optical modulator 460, and the photodetector 465.

According to an embodiment, in a process of forming the silicon layer 410, a silicon material layer may be formed on the buried oxide layer 400, and the silicon material layer may be patterned by lithography, etching, or the like, to form a patterned silicon layer 410. A cladding layer 420 may be stacked on the silicon layer 410. Although not illustrated, a nitride layer may be further positioned on the patterned silicon layer 410.

The waveguide member 450 may be optically connected to the optical components. The waveguide member 450 may function to implement an optical path that confines and transmits light therein within the optical integrated circuit 130. The waveguide member 450 may execute the same function as the waveguide array of the waveguide structure 180. As an example, the waveguide member 450 may include an optical fiber, a silicon waveguide member, a silicon nitride waveguide member, and the like. As another example, the waveguide member 450 may include a core layer and a plurality of cladding layers (lower cladding layers). The waveguide member 450 may be formed of a single structure or a plurality of structures.

The grating coupler 455 may be a medium that receives the optical signal transmitted from the outside through the external optical cable 232 or transmits the optical signal to the outside through the external optical cable 232. The grating coupler 455 may be optically connected to the waveguide member 450. Although the grating coupler 455 is disclosed in the present embodiment, it will be readily apparent to those skilled in the art that an edge coupler may be used. In a case where the edge coupler is used, light may be transmitted and received horizontally through an edge rather than vertically toward the upper surface of the waveguide structure 180.

The optical modulator 460 may modulate the light emitted from the light source element according to a signal to be transmitted to convert the light into the optical signal having information. The optical modulator 460 may be, for example, a phase modulator. In some embodiments, the optical modulator 460 may be, but is not limited to, one of a Mach-Zehnder modulator, a micro-ring modulator, an electro-absorption modulator (EAM), a hybrid LN/Si optical modulator, and a thin-film lithium niobate (TFLN) optical modulator.

The photodetector 465 may generate and output an electric signal according to the received optical signal. The photodetector 465 may be, for example, a positive-intrinsic-negative (PIN) structure including a germanium (Ge) region. Although not illustrated in FIG. 4, the waveguide structure 180 may further include a ring resonator. The ring resonator may be an element that filters a signal of a desired wavelength from the optical signal transmitted through the waveguide member 450. The embodiments of the present disclosure are not limited to the optical components described above, and the waveguide structure 180 may further include a switch, a splitter, a heater, and the like in addition to the components described above.

According to an embodiment, the optical components may be classified into passive components and active components. The waveguide member 450 and the grating coupler 455 may belong to the passive components, and the optical modulator 460 and the photodetector 465 may belong to the active components. The active components may be electrically connected to the electronic components by being electrically connected to contact terminals 470 and 475 penetrating through the cladding layer 420 and exposed on an upper surface of the cladding layer 420. Various structures may be used to electrically connect the active components to the electronic components of the electronic integrated circuit 140, and the structure for electrically connecting the active components to the electronic components is not limited to the structure using the contact terminals 470 and 475 according to the present embodiment.

Hereinabove, an example of the optical integrated circuit 130 including the optical components has been described with reference to FIG. 4, but the present disclosure is not limited to the above-described structure.

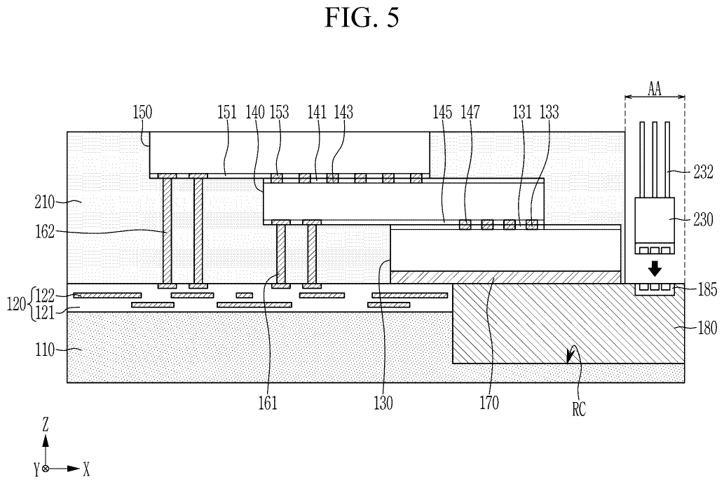

Hereinafter, semiconductor packages according to some embodiments will be described with reference to FIGS. 5 to 9.

FIGS. 5 to 9 are cross-sectional views illustrating the semiconductor packages according to some embodiments. The embodiments illustrated in FIGS. 5 to 9 are substantially similar to the embodiments illustrated in FIGS. 1 to 4, and thus, a description thereof will be omitted and differences will be mainly described.

Referring to FIG. 5, a waveguide structure 180 of the semiconductor packages according to some embodiments may be misaligned with an optical integrated circuit 130.

For example, a center of the waveguide structure 180 may be misaligned or may not be aligned with a center of the optical integrated circuit 130 in the first direction (X direction). That is, the optical integrated circuit 130 may protrude from one side of the waveguide structure 180 toward an inner side of a substrate 110 and away from side surface 110_S of a substrate 110. According to an embodiment, the waveguide structure 180 and the optical integrated circuit 130 may form a step.

Accordingly, a part of the waveguide structure 180 may overlap the optical integrated circuit 130 in the vertical direction (Z direction), and the remaining part of the waveguide structure 180 may not overlap the optical integrated circuit 130 in the vertical direction (Z direction). At this time, the waveguide structure 180 may further include a connector region AA that does not overlap the optical integrated circuit 130 in the vertical direction (Z direction).

According to some embodiments, an internal interconnector 185 may be positioned in the connector region AA of the waveguide structure 180. For example, as illustrated in FIG. 5, the internal interconnector 185 may be positioned on an upper surface of the waveguide structure 180 in the connector region AA. Accordingly, an external interconnector 230 may be connected to the internal interconnector 185 in the vertical direction (Z direction). At this time, a molding layer 210 may not be positioned in the connector region AA of the waveguide structure 180, and the upper surface of the waveguide structure 180 may be exposed in the connector region AA.

Referring to FIG. 6, a recess RC of the semiconductor packages according to some embodiments may have various shapes. For example, the recess RC may be positioned in the substrate 110, and opposite side walls and a bottom surface of the recess RC may be defined by the substrate 110. Accordingly, the waveguide structure 180 positioned in the recess RC may be surrounded by the substrate 110 on three sides. According to some embodiments, opposite side surfaces of the waveguide structure 180 may be in contact with the substrate 110.

Referring to FIG. 7, the semiconductor packages according to some embodiments may further include a solder 125 positioned between a redistribution structure 120 and the substrate 110, e.g., the solder 125 may be positioned between a bottom surface of the redistribution structure 120 and a top surface of the substrate 110. In embodiments, the solder 125 may be positioned on the top surface of the substrate 110 such that the solder 125 does not overlap the waveguide structure 180. According to some embodiments, the redistribution structure 120 may be connected to the substrate 110 via the solder 125.

The solder 125 may be positioned on a lower surface of the redistribution structure 120. The solder 125 may be electrically connected to a plurality of redistribution layers 122 of the redistribution structure 120 and may be electrically connected to a routing line of the substrate 110. The solder 125 may contain a conductive material. For example, the solder 125 may contain tin (Sn), silver (Ag), copper (Cu), manganese (Mn), lead (Pb), and/or an alloy thereof. The solder 125 may include, for example, a solder ball and a solder bump.

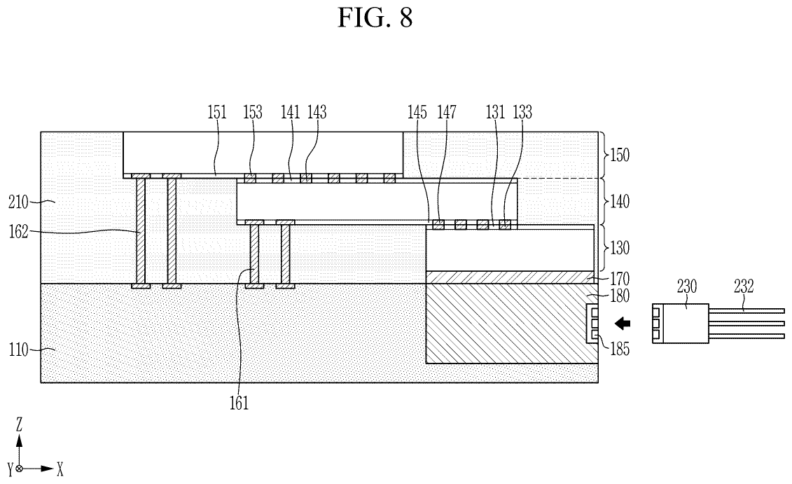

Referring to FIG. 8, the semiconductor packages according to some embodiments may not include the redistribution structure 120. Accordingly, a first conductive post 161 may electrically and physically connect between an electronic integrated circuit 140 and the substrate 110, and a second conductive post 162 may electrically and physically connect between a semiconductor chip 150 and the substrate 110.

According to some embodiments, the upper surface of the waveguide structure 180 may be positioned at substantially the same level as an upper surface of the substrate 110. That is, the upper surface of the waveguide structure 180 may be positioned on the same plane as the upper surface of the substrate 110.

Referring to FIG. 9, the semiconductor chip 150 of the semiconductor packages according to some embodiments may be mounted on the redistribution structure 120.

According to some embodiments, the semiconductor chip 150 may be positioned on the redistribution structure 120 and not on the electronic integrated circuit 140. The semiconductor chip 150 may be positioned while being spaced apart from the electronic integrated circuit 140 in the first direction (X direction). That is, the semiconductor chip 150 may not overlap the electronic integrated circuit 140 in the vertical direction (Z direction).

According to some embodiments, the semiconductor chip 150 may further include a chip solder 156 positioned between the semiconductor chip 150 and the redistribution structure 120. According to some embodiments, the semiconductor chip 150 may be connected to the redistribution structure 120 via the chip solder 156.

The chip solder 156 may be positioned on a lower surface of the semiconductor chip 150. The chip solder 156 may be electrically connected to the semiconductor chip 150 and electrically connected to the plurality of redistribution layers 122 of the redistribution structure 120. The chip solder 156 may contain a conductive material. For example, the chip solder 156 may contain tin (Sn), silver (Ag), copper (Cu), manganese (Mn), lead (Pb), and/or an alloy thereof. The chip solder 156 may include, for example, a chip solder ball and a chip solder bump.

Hereinafter, a semiconductor package manufacturing method according to an embodiment will be described with reference to FIGS. 10 to 21.

FIGS. 10 to 21 are cross-sectional views illustrating the semiconductor package manufacturing method according to an embodiment.

Referring to FIG. 10, the first carrier substrate 500 may be prepared, and an adhesive layer 510 may be formed on the first carrier substrate 500.

According to an embodiment, the first carrier substrate 500 may be a glass wafer. The first carrier substrate 500 may contain, for example, a silicon-based material such as glass or silicon oxide, an organic material, another material such as aluminum oxide, or any combination thereof. The adhesive layer 510 may be an adhesive tape, an adhesive, or the like. According to an embodiment, the adhesive layer 510 may further include an alignment mark layer for disposing the semiconductor package.

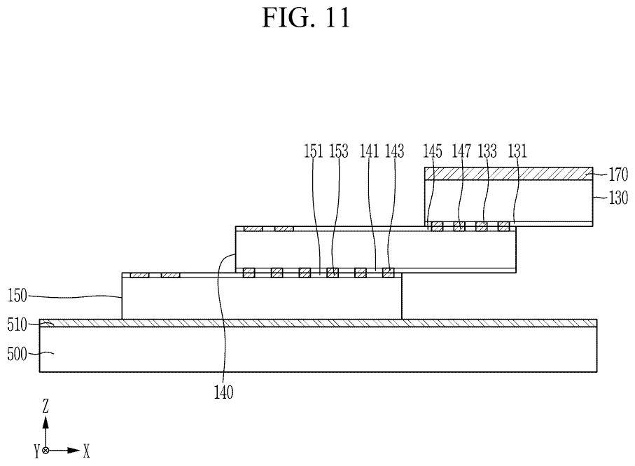

Referring to FIG. 11, the semiconductor chip 150, the electronic integrated circuit 140, and the optical integrated circuit 130 may be sequentially formed on the first carrier substrate 500, and the waveguide layer 170 may be formed on the optical integrated circuit 130.

According to an embodiment, the semiconductor chip 150 may not be aligned with the electronic integrated circuit 140. For example, the center of the semiconductor chip 150 may be misaligned with the center of the electronic integrated circuit 140 in the first direction (X direction). Accordingly, the semiconductor chip 150 and the electronic integrated circuit 140 may form a step. Therefore, one side surface of the semiconductor chip 150 may be aligned with a different boundary from that of one side surface of the electronic integrated circuit 140. That is, neither side surface of the semiconductor chip 150 may be aligned with either side surface of the electronic integrated circuit 140.

According to an embodiment, the semiconductor chip 150 and the electronic integrated circuit 140 may have the chip-to-chip (C2C) structure bonded by the wafer bonding method (for example, hybrid bonding). That is, the lower surface of the semiconductor chip 150 may be bonded to the upper surface of the electronic integrated circuit 140 by hybrid bonding. The description thereof has been provided above with reference to FIGS. 1 to 4 and is thus omitted here.

Further, the electronic integrated circuit 140 may be misaligned or may not be aligned with the optical integrated circuit 130. For example, the center of the electronic integrated circuit 140 may be misaligned with the center of the optical integrated circuit 130 in the first direction (X direction). According to an embodiment, the electronic integrated circuit 140 and the optical integrated circuit 130 may form a step. Accordingly, one side surface of the electronic integrated circuit 140 may be aligned with a different boundary from that of one side surface of the optical integrated circuit 130. That is, neither side surface of the optical integrated circuit 130 may be aligned with either side surface of the electronic integrated circuit 140.

According to an embodiment, the optical integrated circuit 130 may have the chip-to-chip (C2C) structure bonded to the electronic integrated circuit 140 by the wafer bonding method (for example, hybrid bonding). That is, the upper surface of the optical integrated circuit 130 may be bonded to the lower surface of the electronic integrated circuit 140 by hybrid bonding. The description thereof has been provided above with reference to FIGS. 1 to 4 and is thus omitted here.

Then, the waveguide layer 170 may be formed on the optical integrated circuit 130. The waveguide layer 170 may be optically connected to the optical integrated circuit 130. The waveguide layer 170 may include the waveguide. The waveguide may function to implement the optical path that confines and transmits light therein. For example, the waveguide layer 170 may include an optical fiber, a silicon waveguide, a silicon nitride waveguide, and a waveguide including a cladding layer and a core layer, but is not limited thereto.

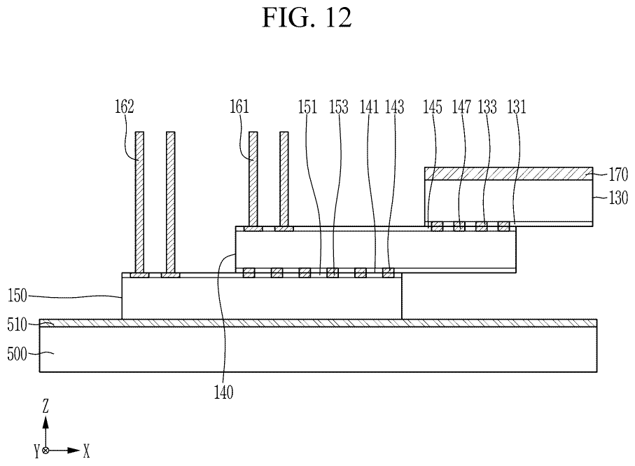

Referring to FIG. 12, the second conductive post 162 may be formed on the semiconductor chip 150, and the first conductive post 161 may be formed on the electronic integrated circuit 140.

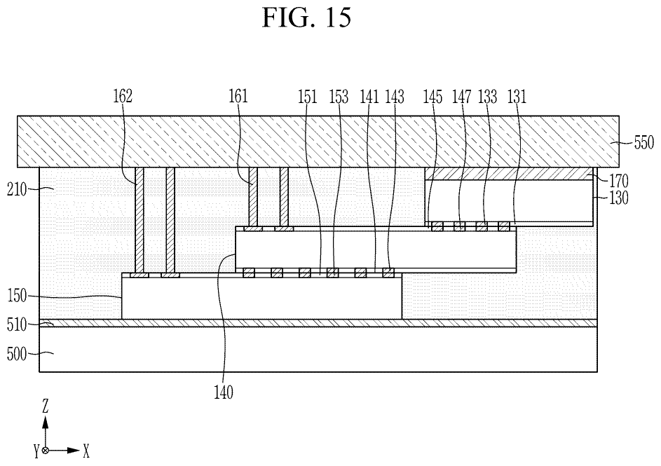

The first conductive post 161 and the second conductive post 162 may extend in the vertical direction (Z direction). The first conductive post 161 may be electrically connected to the electronic integrated circuit 140. The first conductive post 161 may be positioned on the portion of the electronic integrated circuit 140 that does not overlap the optical integrated circuit 130 in the vertical direction (Z direction). The second conductive post 162 may be electrically connected to the semiconductor chip 150. The second conductive post 162 may be positioned on the portion of the semiconductor chip 150 that does not overlap the electronic integrated circuit 140 in the vertical direction (Z direction). According to an embodiment, e.g., FIG. 1, the length of the first conductive post 161 in the vertical direction (Z direction) may be smaller than the length of the second conductive post 162 in the vertical direction (Z direction) as the distance from the first conductive post 161 to the redistribution structure 120 is less that the distance from the second conductive post 162 to the redistribution structure 120. According to an embodiment, e.g., FIG. 15, the length of the first conductive post 161 in the vertical direction (Z direction) may be smaller than the length of the second conductive post 162 in the vertical direction (Z direction) as the distance from the first conductive post 161 to a second carrier substrate 550 is less that the distance from the second conductive post 162 to the second carrier substrate 550. According to an embodiment, the center of the semiconductor chip 150 is misaligned or not aligned with the center of the electronic integrated circuit 140 in the first direction (X direction), and thus, a part of the upper surface of the semiconductor chip 150 may be exposed. Therefore, the second conductive post 162 may be formed on the exposed upper surface of the semiconductor chip 150.

In addition, the center of the electronic integrated circuit 140 is misaligned or not aligned with the center of the optical integrated circuit 130 in the first direction (X direction), and thus, a part of the upper surface of the electronic integrated circuit 140 may be exposed. Therefore, the first conductive post 161 may be formed on the exposed upper surface of the electronic integrated circuit 140.

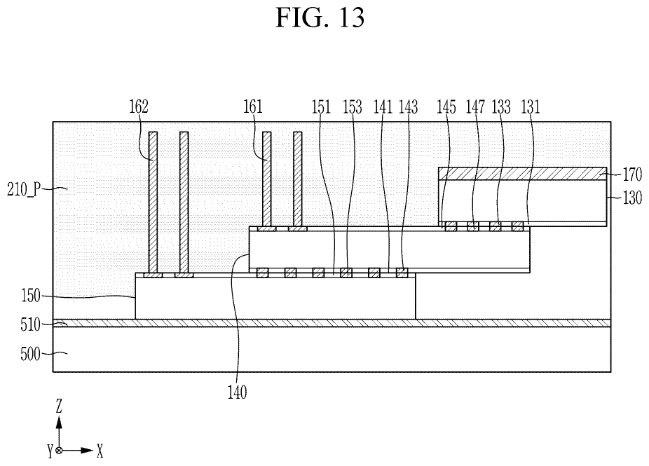

Referring to FIG. 13, a molding material layer 210_P surrounding the optical integrated circuit 130, the electronic integrated circuit 140, and the semiconductor chip 150 may be formed.

The molding material layer 210_P may mold the waveguide structure 180, the optical integrated circuit 130, the electronic integrated circuit 140, and the semiconductor chip 150. The molding material layer 210_P may cover opposite side surfaces and the upper surface of the semiconductor chip 150, opposite side surfaces and the upper surface of the electronic integrated circuit 140, and opposite side surfaces of the optical integrated circuit 130. In addition, the molding material layer 210_P may cover the upper surface of the waveguide structure 170, but is not limited thereto. According to an embodiment, the molding material layer 210_P may have a thickness sufficient to surround the first conductive post 161 and the second conductive post 162.

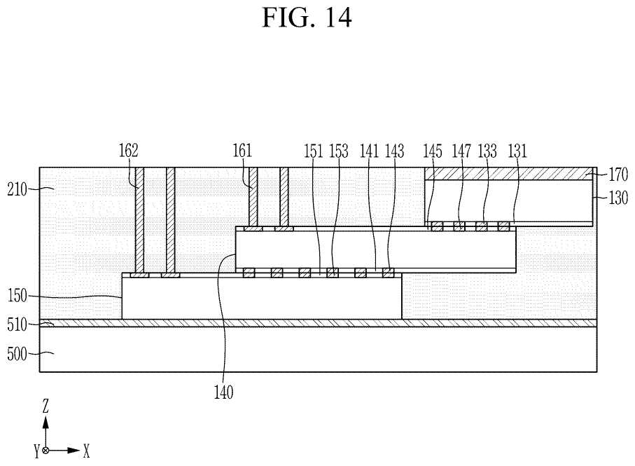

Referring to FIG. 14, the molding layer 210 may be formed by reducing the thickness of the molding material layer 210_P by removing at least a part of the molding material layer 210_P. A process of removing at least a part of the molding material layer 210_P may include a process of flattening an upper surface of the molding material layer 210_P by performing chemical mechanical polishing (CMP). Accordingly, an upper surface of the waveguide layer 170 may be exposed. That is, according to an embodiment, a surface of the molding layer 210_P may be on a same plane as the surface of the waveguide layer 170 opposite to the optical integrated circuit 130.

Referring to FIG. 15, a second carrier substrate 550 may be attached on the upper surface of the molding layer 210, the upper surface of the waveguide layer 170, an upper surface of the first conductive post 161, and an upper surface of the second conductive post 162.

According to an embodiment, the second carrier substrate 550 may be a glass wafer. The second carrier substrate 550 may contain, for example, a silicon-based material such as glass or silicon oxide, an organic material, another material such as aluminum oxide, or any combination thereof. According to an embodiment, the second carrier substrate 550 may further include an adhesive layer on a lower surface.

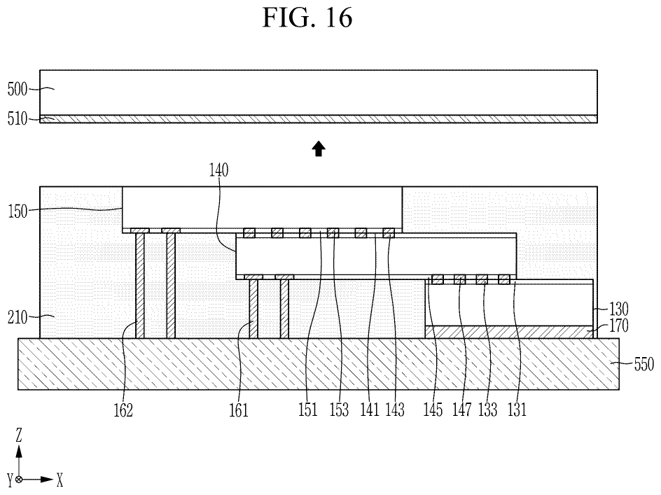

Referring to FIG. 16, the semiconductor package to which the second carrier substrate 550 is attached may be flipped, and the first carrier substrate 500 and the adhesive layer 510 may be removed. Accordingly, the molding layer 210 may not be positioned on the upper surface of the semiconductor chip 150. The upper surface of the molding layer 210 may be positioned on the same plane as the upper surface of the semiconductor chip 150.

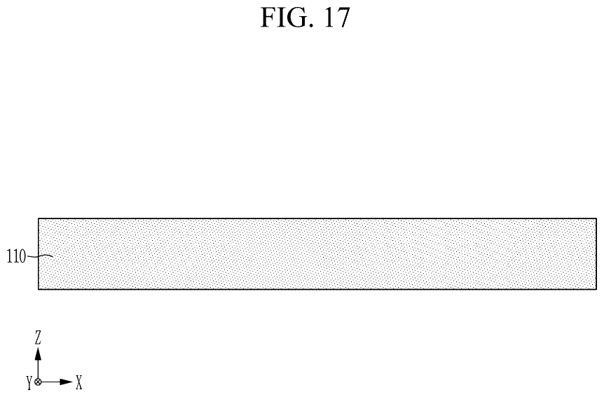

Referring to FIG. 17, the substrate 110 is prepared. The substrate 110 may be a substrate for a package, and may be, for example, a printed circuit board (PCB) or a ceramic substrate. In a case where the substrate 110 is a printed circuit board, the substrate 110 may be made of at least one material selected from a phenol resin, an epoxy resin, and a polyimide. The substrate 110 may have the upper surface and the lower surface facing each other. The substrate 110 may include integrated circuits. The substrate 110 may include one or more routing lines.

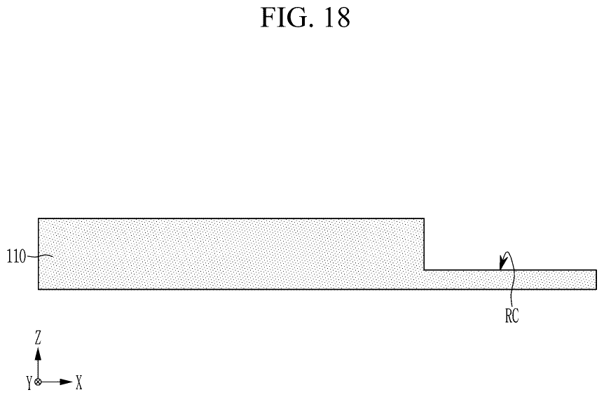

Referring to FIG. 18, at least a part of the substrate 110 may be etched to form the recess RC.

The recess RC may be formed at the edge of the substrate 110. For example, the recess RC may be positioned at one end of the substrate 110, and one side wall and the bottom surface of the recess RC may be defined by the substrate 110. Accordingly, the substrate 110 may have a step at the edge. However, the present disclosure is not limited thereto, and the recess RC may be positioned in the substrate 110, and opposite side walls of the recess RC may be defined by the substrate 110.

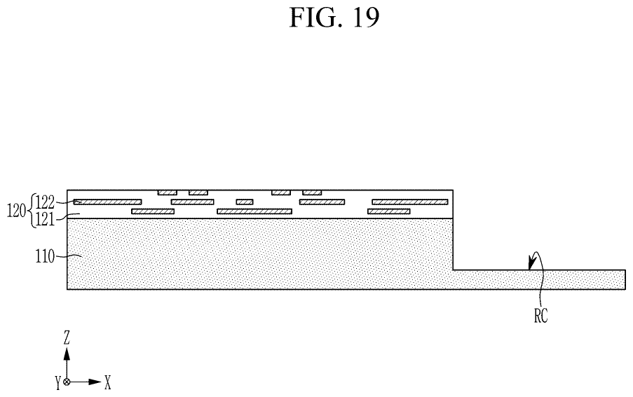

Referring to FIG. 19, the redistribution structure 120 may be formed on the substrate 110. The redistribution structure 120 may be positioned on the substrate 110. The redistribution structure 120 may be positioned directly on the upper surface of the substrate 110. The redistribution structure 120 may not be positioned in the recess RC positioned in the substrate 110. The side surface of the redistribution structure 120 may be aligned with the same boundary as that of one sidewall of the recess RC. The redistribution structure 120 may be electrically connected to the routing line of the substrate 110.

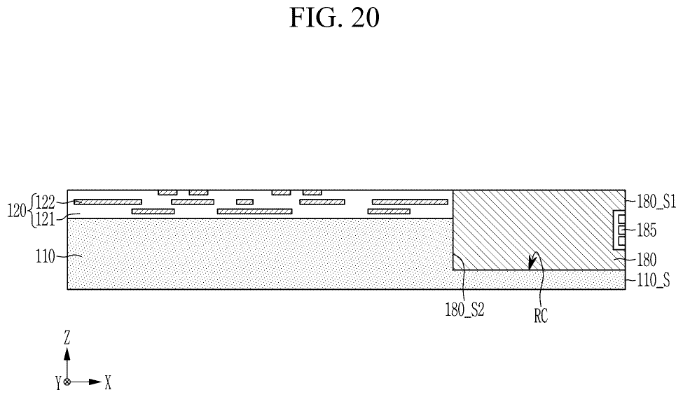

Referring to FIG. 20, the waveguide structure 180 may be formed in the recess RC of the substrate 110.

The waveguide structure 180 may be positioned in the recess RC of the substrate 110. That is, the waveguide structure 180 may be embedded in the substrate 110. At this time, the upper surface of the waveguide structure 180 may protrude in the vertical direction (Z direction) from the upper surface of the substrate 110. That is, the upper surface of the waveguide structure 180 may be positioned at a higher level than the upper surface of the substrate 110. The upper surface of the waveguide structure 180 may be positioned further from the lower surface of the substrate 110 than the upper surface of the substrate 110.

According to an embodiment, the redistribution structure 120 may include the plurality of insulating layers 121, the plurality of redistribution layers 122, and the plurality of redistribution vias. According to an embodiment, the plurality of insulating layers 121 and the plurality of redistribution layers 122 of the redistribution structure 120 may be in contact with the upper surface of the substrate 110. For example, the plurality of redistribution layers 122 of the redistribution structure 120 may be in direct contact with and electrically connected to the routing lines positioned in the substrate 110. However, the present disclosure is not limited thereto, and the redistribution structure 120 may have a chip shape and may be electrically connected to the substrate 110 through the bumps connected to the plurality of redistribution layers 122 as in the embodiment illustrated in FIG. 7.

According to an embodiment, the side surface of the waveguide structure 180 may be aligned with the same boundary as that of the side surface 110_S of the substrate 110. For example, the waveguide structure 180 may have the first side surface 180_S1 and the second side surface 180_S2 facing the first side surface 180_S1, and the first side surface 180_S1 of the waveguide structure 180 may be aligned with the same boundary as that of the side surface 110_S of the substrate 110. The first side surface 180_S1 of the waveguide structure 180 may be positioned at one end of the substrate 110. The first width W1 of the recess RC in the first direction (X direction) may be substantially the same as the width of the waveguide structure 180 in the first direction (X direction), but is not limited thereto. The second side surface 180_S2 of the waveguide structure 180 may be in contact with one side wall of the recess RC. In addition, the second side surface 180_S2 of the waveguide structure 180 may be in contact with the side surface of the rewiring structure 120, but is not limited thereto. The second side surface 180_S2 of the waveguide structure 180 may be aligned with the same boundary as that of a side surface of the optical integrated circuit 130 described below. The second side surface 180_S2 of the waveguide structure 180 may be opposite to the first side surface 180_S1.

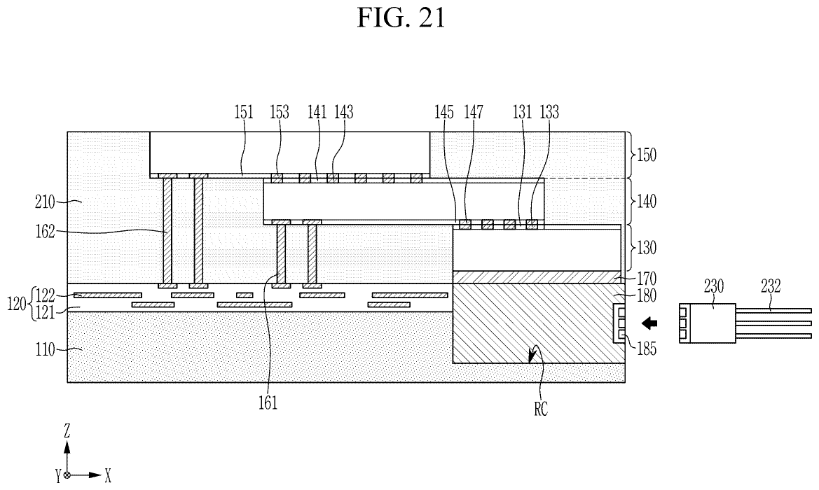

Referring to FIG. 21, the semiconductor package including the optical integrated circuit 130, the electronic integrated circuit 140, and the semiconductor chip 150 illustrated in FIG. 16 may be attached on the substrate 110. Accordingly, the waveguide structure 180 and the waveguide layer 170 may be optically connected to each other. In addition, the first conductive post 161 and the second conductive post 162 may be electrically connected to the redistribution structure 120. As a result, the semiconductor package according to the embodiment illustrated in FIGS. 1 to 4 may be formed.

Although the embodiment of the present disclosure has been described above, the present disclosure is not limited thereto, and it is possible to carry out various modifications within the scope of the claims, the detailed description of the disclosure, and the accompanying drawings. It goes without saying that the modifications fall within the scope of the present disclosure.

What is claimed is:

1. A semiconductor package comprising:
a substrate having a recess at an edge;
a waveguide structure in the recess, the waveguide structure comprising an internal interconnector configured to be connected to an external interconnector;
an optical integrated circuit above the waveguide structure, the optical integrated circuit optically connected to the waveguide structure;
an electronic integrated circuit on the optical integrated circuit;
a semiconductor chip on the electronic integrated circuit;
a first conductive post connecting the substrate and the electronic integrated circuit; and
a second conductive post connecting the substrate and the semiconductor chip,
wherein a first side surface of the waveguide structure is aligned with a side surface of the substrate.

2. The semiconductor package of claim 1, further comprising:
a redistribution structure between the substrate and the first conductive post, wherein the electronic integrated circuit is connected to the substrate through the first conductive post and the redistribution structure, or
the redistribution structure between the substrate and the second conductive post,
wherein the semiconductor chip is connected to the substrate through the second conductive post and the redistribution structure.

3. The semiconductor package of claim 2, wherein the waveguide structure protrudes from an upper surface of the substrate.

4. The semiconductor package of claim 2, wherein a distance between an upper surface of the redistribution structure and a bottom surface of the substrate is equal to a distance between an upper surface of the waveguide structure and the bottom surface of the substrate, or
wherein the distance between the upper surface of the redistribution structure and the bottom surface of the substrate is equal to a distance between an upper surface of a waveguide layer above the waveguide structure and the bottom surface of the substrate.

5. The semiconductor package of claim 1, wherein the internal interconnector is on the first side surface of the waveguide structure.

6. The semiconductor package of claim 5, wherein the waveguide structure further has a second side surface opposite the first side surface, and
wherein the second side surface of the waveguide structure is aligned with a side surface of the optical integrated circuit in a vertical direction.

7. The semiconductor package of claim 6, wherein a side surface of the electronic integrated circuit is not aligned with the second side surface of the waveguide structure in the vertical direction.

8. The semiconductor package of claim 1, wherein the waveguide structure comprises a connector region on the first side surface of the waveguide structure, and the connector region does not overlap the optical integrated circuit in the vertical direction, and
wherein the internal interconnector is in the connector region of the waveguide structure.

9. The semiconductor package of claim 1, wherein a part of the semiconductor chip overlaps the electronic integrated circuit in a horizontal direction, and a remaining part of the semiconductor chip does not overlap the electronic integrated circuit.

10. The semiconductor package of claim 9, wherein the semiconductor chip and the electronic integrated circuit form a step.

11. The semiconductor package of claim 9, wherein a length of the first conductive post is smaller than a length of the second conductive post.

12. The semiconductor package of claim 1, wherein a part of the electronic integrated circuit overlaps the waveguide structure, and a remaining part of the electronic integrated circuit does not overlap the waveguide structure.

13. The semiconductor package of claim 1, wherein the optical integrated circuit comprises a first bonding insulating layer on an upper side of the optical integrated circuit, and a first contact pad penetrating through the first bonding insulating layer; and
wherein the electronic integrated circuit comprises a second bonding insulating layer on a lower side of the electronic integrated circuit, and a second contact pad penetrating through the second bonding insulating layer,
wherein the first contact pad and the second contact pad are connected, and
wherein an upper surface of the first bonding insulating layer is in contact with a lower surface of the second bonding insulating layer.

14. The semiconductor package of claim 1, further comprising:
a molding layer surrounding at least respective parts of the optical integrated circuit, the electronic integrated circuit, and the semiconductor chip,
wherein an upper surface of the molding layer is on a same plane as an upper surface of the semiconductor chip.

15. A semiconductor package comprising:
a substrate having a recess;
a waveguide structure in the recess, the waveguide structure comprising a waveguide array;
an optical integrated circuit above the waveguide structure, the optical integrated circuit optically connected to the waveguide structure;
an electronic integrated circuit on the optical integrated circuit;
a semiconductor chip on the electronic integrated circuit;
a first conductive post connecting the substrate and the electronic integrated circuit; and
a second conductive post connecting the substrate and the semiconductor chip,
wherein a first side surface of the electronic integrated circuit is not aligned with a first side surface of the optical integrated circuit, and
a first side surface of the semiconductor chip is not aligned with a second side surface of the electronic integrated circuit.

16. The semiconductor package of claim 15, wherein a center of the electronic integrated circuit and a center the optical integrated circuit are misaligned, and a center of the semiconductor chip and the center of the electronic integrated circuit are misaligned.

17. The semiconductor package of claim 15, further comprising:
a redistribution structure between the substrate and the first conductive post and between the substrate and the second conductive post,
wherein an upper surface of the redistribution structure is on a same plane as an upper surface of the waveguide structure.

18. The semiconductor package of claim 15, wherein a first side surface of the waveguide structure is not aligned with a side surface of the substrate in a vertical direction, or
wherein the first side surface of the waveguide structure and a second side surface of the waveguide structure that is opposite to the first side surface of the waveguide structure are at least partially connected to the substrate in the vertical direction.

19. The semiconductor package of claim 15, further comprising:
a molding layer surrounding at least respective parts of the optical integrated circuit, the electronic integrated circuit, and the semiconductor chip,
wherein a distance between an upper surface of the molding layer and a lower layer of the substrate is equal to a distance between an upper surface of the semiconductor chip and the lower layer of the substrate.

20. A semiconductor package comprising:
a substrate having a recess;
a waveguide structure in the recess, the waveguide structure comprising a waveguide array;
an optical integrated circuit above the waveguide structure, the optical integrated circuit optically connected to the waveguide structure;
an electronic integrated circuit on the optical integrated circuit, wherein a center of the electronic integrated circuit is misaligned with a center of the optical integrated circuit;
a semiconductor chip on the electronic integrated circuit, wherein a center of the semiconductor chip being is misaligned with the center of the electronic integrated circuit;
a redistribution structure above the substrate;
a first conductive post electrically connecting the redistribution structure and the electronic integrated circuit; and
a second conductive post electrically connecting the redistribution structure and the semiconductor chip,
wherein a distance between an upper surface of the waveguide structure and a lower surface of the substrate is equal to a distance between an upper surface of the redistribution structure and the lower surface of the substrate, and
wherein a side surface of the waveguide structure is aligned with a side surface of the substrate.
